(19) United States
(12) Patent Application Publication
(10) Pub. No.: US 2026/0033379 A1
(43) Pub. Date: Jan. 29, 2026

(54) ENCAPSULATED PACKAGE WITH CARRIER HAVING TIE BAR VERTICALLY COVERED BY ENCAPSULANT

(71) Applicant: Infineon Technololgies AG, Neubiberg (DE)

(72) Inventors: Emmanuel Inoferio LIVELO, Melaka (MY); Aira Lourdes Baring VILLAMOR, Melaka (MY); Mohd Hirzarul Hafiz MOHD TAHIR, Melaka (MY); Meng How CHONG, Melaka (MY)

(73) Assignee: Infineon Technologies AG, Neubiberg (DE)

(21) Appl. No.: 19/229,676

(22) Filed: Jun. 5, 2025

(30) Foreign Application Priority Data
Jul. 26, 2024 (DE) 10 2024 207 041.6

(51) Int. Cl. H01L 23/31; H01L 21/56; H01L 23/495

(52) U.S. Cl. CPC H01L 23/3107; H01L 21/561; H01L 23/49541

(57) ABSTRACT

A package and method is disclosed. In one example, the package comprises a carrier comprising a component mounting area from which a tie bar extends, the tie bar being configured for being clamped by an encapsulation tool pin during encapsulation, an electronic component mounted on the component mounting area, and an encapsulant encapsulating at least part of the electronic component and part of the carrier and having a sidewall with a sidewall recess which is vertically displaced with respect to a part of the tie bar, wherein the encapsulant vertically covers an entire horizontal surface portion of the tie bar facing the sidewall recess.

### CROSS-REFERENCE TO RELATED APPLICATION

This Utility Patent Application claims priority to German Patent Application No. 10 2024 207 041.6 filed Jul. 26, 2024, which is incorporated herein by reference.

### BACKGROUND

### Technical Field

Various embodiments relate generally to a package, and a method of manufacturing a package.

### Description of the Related Art

Packages may be denoted as encapsulated electronic components with electrical connections extending out of the encapsulant and being mountable on an electronic periphery, for instance on a printed circuit board.

Packaging cost is an important driver for the industry. Related with this are performance, dimensions and reliability. The different packaging solutions are manifold and have to address the needs of the application.

### SUMMARY

There may be a need to provide a possibility to manufacture packages with high device reliability and in a simple and quick way.

According to an exemplary embodiment, a package is provided which comprises a carrier comprising a component mounting area from which a tie bar extends, the tie bar being configured for being clamped by an encapsulation tool pin during encapsulation, an electronic component mounted on the component mounting area, and an encapsulant encapsulating at least part of the electronic component and part of the carrier and having a sidewall with a sidewall recess which is vertically displaced with respect to a part of the tie bar, wherein the encapsulant vertically covers an entire horizontal surface portion of the tie bar facing the sidewall recess.

According to another exemplary embodiment, a method of manufacturing a package is provided, wherein the method comprises providing a carrier comprising a component mounting area from which a tie bar extends, mounting an electronic component on the component mounting area, encapsulating at least part of the electronic component and part of the carrier by an encapsulant, wherein the tie bar is clamped by an encapsulation tool pin during at least part of the encapsulating, and forming the encapsulant with a sidewall having a sidewall recess which is partially defined by the encapsulation tool pin and which is vertically displaced with respect to a part of the tie bar so that the encapsulant vertically covers an entire horizontal surface portion of the tie bar facing the sidewall recess.

According to an exemplary embodiment, an encapsulated (in particular molded) package is provided which has a carrier (which may be made for instance of a metallic material, in particular based on a leadframe structure) with a component mounting area (such as a die pad) carrying at least one electronic component (such as a semiconductor chip). At least one tie bar may extend laterally from the component mounting area. The tie bar may have the function to connect neighbored carriers or component mounting areas of an integrated carrier structure before singulation to thereby provide stability. In addition, the tie bar may be used to be clamped down by an encapsulation tool pin during the process of encapsulating carrier and electronic component by an encapsulant (such as a mold compound). This clamping of the tie bar together with the component mounting area of the carrier may prevent an undesired flow of still flowable encapsulant to the bottom side of the carrier which may allow to avoid undesired phenomena such as mold flash or bleeding of encapsulant material into unintentional regions of the package. As a fingerprint of the temporary presence of the encapsulation tool pin during at least part of an encapsulation process, the encapsulant encapsulating electronic component and carrier may have a sidewall with a sidewall recess where a portion of the encapsulation tool pin has been located during encapsulation. More specifically, a spatial region where the encapsulation tool pin has been positioned during encapsulation may first lead to a hole in the encapsulant having an inverse shape as the encapsulation tool pin which may be retracted at the end of an encapsulation process. In a singulation process of singulating individual packages after encapsulation, encapsulant material adjacent to such a hole may be removed together with tie bar material, for instance by a mechanical sawing process. This removal may convert the inverse pin-shaped hole into the sidewall recess in the encapsulant, which may be a notch-shaped blind hole having a closed bottom delimited by encapsulant material. Thus, the recess may be vertically displaced with respect to a part of the tie bar. More specifically, the recess may be located vertically above an upper surface portion of the tie bar spaced by encapsulant material in between. Advantageously, the encapsulant may vertically cover an entire horizontal surface portion of the tie bar facing the sidewall recess. For instance in a plan view into the recess from above, the entire surface of the recess may be delimited by encapsulant material rather than by tie bar material. As a result, undesired burrs may be reliably prevented in the recess, which burrs may be generated when sawing through the tie bar, which may be metallic. Due to the described package architecture and corresponding manufacturing process, artefacts such as mold flash and/or burrs in the recess may be efficiently suppressed, while simultaneously allowing a simple and efficient manufacture of the package. As a result, packages may be provided which can be manufactured with high device reliability and in a simple and quick way.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a side view of a package according to an exemplary embodiment.

FIG. 2 illustrates an overview and a detail of an arrangement during manufacture of a package according to an exemplary embodiment.

FIG. 3 illustrates an encapsulation tool pin used during manufacture of a package according to an exemplary embodiment.

FIG. 4 illustrates a preform of packages during a batch manufacture according to an exemplary embodiment.

FIG. 5 illustrates another preform of a package during a batch manufacture according to an exemplary embodiment.

FIG. 6 illustrates a detail of FIG. 5.

FIG. 7 illustrates a three-dimensional view of a package according to an exemplary embodiment.

FIG. 8 illustrates a detail of a preform of the package of FIG. 7.

FIG. 9 illustrates different views of a package according to an exemplary embodiment.

FIG. 10 illustrates a detail of a package according to an exemplary embodiment.

FIG. 11 illustrates a detail of a package according to another exemplary embodiment.

FIG. 12 illustrates an encapsulation tool used for manufacturing a package according to an exemplary embodiment.

FIG. 13 illustrates a preform of packages during a batch manufacture according to an exemplary embodiment.

### DETAILED DESCRIPTION

There may be a need to provide a possibility to manufacture packages with high device reliability and in a simple and quick way.

According to an exemplary embodiment, a package is provided which comprises a carrier comprising a component mounting area from which a tie bar extends, the tie bar being configured for being clamped by an encapsulation tool pin during encapsulation, an electronic component mounted on the component mounting area, and an encapsulant encapsulating at least part of the electronic component and part of the carrier and having a sidewall with a sidewall recess which is vertically displaced with respect to a part of the tie bar, wherein the encapsulant vertically covers an entire horizontal surface portion of the tie bar facing the sidewall recess.

According to another exemplary embodiment, a method of manufacturing a package is provided, wherein the method comprises providing a carrier comprising a component mounting area from which a tie bar extends, mounting an electronic component on the component mounting area, encapsulating at least part of the electronic component and part of the carrier by an encapsulant, wherein the tie bar is clamped by an encapsulation tool pin during at least part of the encapsulating, and forming the encapsulant with a sidewall having a sidewall recess which is partially defined by the encapsulation tool pin and which is vertically displaced with respect to a part of the tie bar so that the encapsulant vertically covers an entire horizontal surface portion of the tie bar facing the sidewall recess.

According to an exemplary embodiment, an encapsulated (in particular molded) package is provided which has a carrier (which may be made for instance of a metallic material, in particular based on a leadframe structure) with a component mounting area (such as a die pad) carrying at least one electronic component (such as a semiconductor chip). At least one tie bar may extend laterally from the component mounting area. The tie bar may have the function to connect neighbored carriers or component mounting areas of an integrated carrier structure before singulation to thereby provide stability. In addition, the tie bar may be used to be clamped down by an encapsulation tool pin during the process of encapsulating carrier and electronic component by an encapsulant (such as a mold compound). This clamping of the tie bar together with the component mounting area of the carrier may prevent an undesired flow of still flowable encapsulant to the bottom side of the carrier which may allow to avoid undesired phenomena such as mold flash or bleeding of encapsulant material into unintentional regions of the package. As a fingerprint of the temporary presence of the encapsulation tool pin during at least part of an encapsulation process, the encapsulant encapsulating electronic component and carrier may have a sidewall with a sidewall recess where a portion of the encapsulation tool pin has been located during encapsulation. More specifically, a spatial region where the encapsulation tool pin has been positioned during encapsulation may first lead to a hole in the encapsulant having an inverse shape as the encapsulation tool pin which may be retracted at the end of an encapsulation process. In a singulation process of singulating individual packages after encapsulation, encapsulant material adjacent to such a hole may be removed together with tie bar material, for instance by a mechanical sawing process. This removal may convert the inverse pin-shaped hole into the sidewall recess in the encapsulant, which may be a notch-shaped blind hole having a closed bottom delimited by encapsulant material. Thus, the recess may be vertically displaced with respect to a part of the tie bar. More specifically, the recess may be located vertically above an upper surface portion of the tie bar spaced by encapsulant material in between. Advantageously, the encapsulant may vertically cover an entire horizontal surface portion of the tie bar facing the sidewall recess. For instance in a plan view into the recess from above, the entire surface of the recess may be delimited by encapsulant material rather than by tie bar material. As a result, undesired burrs may be reliably prevented in the recess, which burrs may be generated when sawing through the tie bar, which may be metallic. Due to the described package architecture and corresponding manufacturing process, artefacts such as mold flash and/or burrs in the recess may be efficiently suppressed, while simultaneously allowing a simple and efficient manufacture of the package. As a result, packages may be provided which can be manufactured with high device reliability and in a simple and quick way.

### DESCRIPTION OF FURTHER EXEMPLARY EMBODIMENTS

In the following, further exemplary embodiments of the package, and the method will be explained.

In the context of the present application, the term “package” may particularly denote an electronic device which may comprise one or more electronic components mounted on a carrier. Said constituents of the package may be encapsulated at least partially by an encapsulant. Optionally, one or more electrically conductive interconnect bodies (such as bond wires and/or clips) may be implemented in a package, for instance for electrically coupling the electronic component with the carrier and/or with leads.

In the context of the present application, the term “carrier” may particularly denote a support structure (which may be at least partially electrically conductive) which serves as a mechanical support for the one or more electronic components to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may comprise a die pad.

In the context of the present application, the term “component mounting area” may particularly denote a section of the carrier which is configured for mounting at least one electronic component thereon. For instance, the component mounting area may be a die pad. In an embodiment, the component mounting area may be a planar plate-like metallic body or region.

In the context of the present application, the term “tie bar” may particularly denote a web, beam or bar which may extend from a component mounting area of a carrier. For example, such a tie bar may be made of the same material as the component mounting area and may be integrally connected with the component mounting area. Such a tie bar may be provided for connection of said component mounting area of the carrier with another component mounting area of an adjacent carrier of a multi-carrier structure such as a leadframe. Hence, such a tie bar may be used for integrally connecting various carriers in a common carrier structure (such as a leadframe) prior to singulation into individual packages. Thus, said tie bar may connect different carriers of a leadframe and may thereby increase the mechanical stability during manufacture. As a consequence, highly accurate packages may be obtained.

In the context of the present application, the term “clamping the tie bar by an encapsulation tool pin” may particularly denote a process during which a stationary (or fix), retractable, liftable or removable encapsulation tool pin of an encapsulation tool (for instance a mold tool) may press the tie bar of the carrier against a support surface (for instance of the encapsulation tool) during the encapsulation process to thereby clamp the tie bar together with the component mounting area onto the support surface for preventing flow of encapsulant material to an opposing side of the carrier. This may suppress encapsulation artefacts, such as mold flash.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a substantially electrically insulating material surrounding at least part of an electronic component and part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity.

In the context of the present application, the term “a sidewall of the encapsulant with a sidewall recess which is vertically displaced with respect to a part of the tie bar” may particularly denote a (preferably vertical) encapsulant sidewall in which a hole is formed extending from an upper main surface of the encapsulant and ending vertically above the tie bar while the hole does not extend up to the tie bar. For instance, such a recess may be a notch-type blind hole. Such a recess may be delimited exclusively by encapsulant material (and in particular not by tie bar material).

In the context of the present application, the term “the encapsulant vertically covers an entire horizontal surface portion of the tie bar facing the sidewall recess” may particularly denote that a vertical gap between a bottom side of said sidewall recess and a top of said tie bar may be filled with encapsulant material, preferably by encapsulant material only. Consequently, it may be possible that no tie bar material is exposed in said sidewall recess, in particular not at a bottom of the sidewall.

In an embodiment, the tie bar is laterally exposed at said sidewall of the encapsulant. Tie bars may have the function of temporarily interconnecting, during a batch manufacturing process of producing multiple packages in parallel, adjacent carriers of a multi-carrier structure, such as a leadframe. When individual packages are singulated in particular by mechanical sawing, the process saws predominantly through encapsulant material and to a much smaller extent through tie bar material, thereby exposing also tie bars at the obtained (in particular vertical) sidewalls. In a readily manufactured package, the tie bar may form part of a sidewall of a package. For example, a ratio between a surface area of an exposed tie bar at a respective sawn side flank and an entire surface area of the respective sawn side flank may be less than 10%, in particular less than 5%, more particularly less than 3%. Thus, sawing may be carried out through material of the (in particular mold-type) encapsulant in combination with only a very limited amount of material of the metallic tie bar(s). Said highly limited tie bar sawing may saw through only a few percent surface area of metal material which provides the advantage of high-speed sawing substantially through encapsulant material.

In an embodiment, said sidewall is a vertical sidewall. When said sidewall is formed during singulating packages by a mechanical sawing process involving a mechanical sawing blade, vertical sidewalls of the package may be the result.

In an embodiment, said sidewall has a sawn texture. Correspondingly, the method may comprise forming the sidewall of the encapsulant by mechanically sawing. In the context of the present application, the term “sawn texture of side flanks or vertical sidewalls” may particularly denote a surface structure or surface profile on a side surface of an encapsulant being defined by sawing. Preferably, said sawing process is a mechanical sawing process using a saw blade. Alternatively, also laser sawing is possible. Due to such a sawing process, in particular mechanical sawing process using a saw blade, a rough surface texture (in particular having a roughness Ra of more than 0.8 μm, in particular between 0.8 μm and 5 μm, for instance around 1 μm) is obtained. Such a rough characteristic of a sawn side flank is combined with the formation of microscopic scratches, marks, rills or corrugations formed by the sawing tool. For instance, a mechanical saw blade may have polyimide bound diamond bodies used for sawing which may for example create the mentioned sawn texture. In particular, a sawn texture of the at least one side flank may comprise a roughness Ra of more than 0.8 μm in combination with corrugations having larger dimensions compared to dimensions of protrusions and indentations relating to a said roughness. The roughness of a surface may be defined as and may be measured as the centerline average height Ra. Ra is the arithmetic mean value of all distances of the profile from the centerline. For instance, the measurement or determination of roughness Ra of the sawn surface may be carried out according to DIN EN ISO 4287:2010. A saw used for forming the sawn texture may be denoted as a tool comprising a tough saw blade with a hard-toothed edge. Such a saw may be used to cut through encapsulant material and optionally also through metallic material of the one or more tie bars by placing the tooth edge against the material and moving it forcefully forth and less forcefully back or continuously forward. For instance, a powered circular saw blade may be used for this purpose. At a sawn side flank of an encapsulant, in particular a sawn side flank of a mold compound, a broken surface may be obtained at which also filler particles are sawn at the surface of the sawn side flank. As a consequence, a sawn side flank may be defined by material of the above-described matrix of the encapsulant and partially also by cut non-coated filler particles.

In an embodiment, the carrier comprises a further tie bar extending from the component mounting area and configured for being clamped by a further encapsulation tool pin during encapsulation, wherein the encapsulant has a further sidewall with a further sidewall recess which is vertically displaced with respect to a part of the further tie bar, and wherein the encapsulant vertically covers an entire horizontal surface portion of the further tie bar facing the further sidewall recess. When providing a plurality of tie bars which can be clamped onto a counter surface by an encapsulation tool pin or the like during encapsulation, undesired tilting of the component mounting area of the carrier can be inhibited even more reliably or efficiently. The different tie bars may extend from different edges of the component mounting area for a more balanced pressing characteristics. The features described herein for the tie bar may apply also to the further tie bar.

In an embodiment, the tie bar and the further tie bar extend from opposing sides of the component mounting area, wherein the sidewall and the further sidewall are opposing sidewalls of the encapsulant. To put it shortly, the above described geometry of sidewall, recess and tie bar may be realized in the same fashion at an opposing sidewall with an opposing recess and an opposing tie bar. For example, the tie bar and the further tie bar may have the same shape and dimension for obtaining a symmetrical package architecture. For instance, two of four side edges of a substantially rectangular component mounting area may be provided for forming tie bars, whereas the other two side edges may be provided for providing or connecting leads or lead sections. This may result in a compact design of the package.

In an embodiment, the sidewall recess is tapering from a main surface of the encapsulant towards the tie bar. This geometry is the fingerprint of an encapsulation tool pin with tapering end section extending into the encapsulant and pressing on a tie bar during the manufacturing process. Even when a resulting circumferentially closed blind hole in the encapsulant is converted into a sidewall recess by a mechanical sawing process, the tapering characteristics may be maintained for the sidewall recess.

In an embodiment, a vertical thickness of a portion of the encapsulant which vertically covers the entire horizontal surface portion of the tie bar facing the sidewall recess is in a range from 0.1 mm to 0.3 mm, for instance at minimum. A vertical depth of an encapsulant spacer, layer or skin between tie bar and bottom of the sidewall recess in the mentioned range reliably ensures that no tie bar material is exposed in the sidewall recess for preventing burr in the sidewall recess. At the same time, the mentioned range ensures that this encapsulant spacer is maintained reliably even under consideration of tolerances.

In an embodiment, the sidewall recess is a blind hole-notch. Such a blind hole-notch has, as a blind hole does, a closed bottom avoiding exposure of an upper or facing vertical tie bar surface. Such a blind hole-notch extends, as a notch does, horizontally into the sidewall of the encapsulant.

In an embodiment, the sidewall is delimited exclusively by material of the encapsulant and of the tie bar. Thus, the at least one (preferably vertical) sidewall, which may be a sawn side flank of the package, may be defined, in particular exclusively, by the encapsulant and a (in particular metallic) tie bar connected to the component mounting area of the carrier. The tie bar may be used for integrally connecting various carriers in a common carrier structure (such as a leadframe) prior to singulation into individual packages and may therefore be partially exposed upon singulation.

In an embodiment, the package comprises one or more electrically conductive lead sections, in particular at least one of which being integrally formed with the component mounting area and/or at least one of which being formed separately from the component mounting area, extending out of the encapsulant at one or two slanted sidewalls of the encapsulant, said one or two slanted sidewalls in particular having a molded texture. Each lead section may comprise one or more leads. At least one lead section may be integrally formed with the component mounting area and the tie bar(s). Additionally or alternatively, at least one lead section may be formed as a separate body with respect to the component mounting area and the tie bar(s), and may be electrically coupled with the component mounting area and/or at least one electronic component mounted thereon by one or more electrically conductive connection structures (such as bond wires and/or clips). For example, lead sections may be arranged along edges of the component mounting area at which no tie bars are present. In the context of the present application, the term “lead” may in particular denote an electrically conductive (for instance strip shaped) element (which may be planar or bent) which may be assigned functionally to the carrier and which serves for contacting the electronic component with an exterior of the package. For instance, a lead may be partially encapsulated and partially exposed with respect to an encapsulant. When the carrier forms part of a leadframe, leads may surround a die pad of the carrier, for instance at two opposing sides. The one or more leads may or may not form part of the carrier.

In an embodiment, said one or two slanted sidewalls may have a molded texture. Correspondingly, the method may comprise forming a slanted sidewall of the encapsulant by a slanted sidewall of an encapsulation tool cavity. This may lead to a molded texture. In the context of the present application, the term “molded texture” may particularly denote a characteristic surface profile of a side flank formed by molding. In particular, such a molded texture may comprise a smooth surface (in particular having a lower surface roughness Ra than a side flank with a sawn texture) with microscopic surface pixels corresponding to filler particles added to a mold compound, appearing at an exterior surface of a mold-type encapsulant and being coated with molded encapsulant material (in particular mold resin).

In an embodiment, a main surface of the component mounting area facing away from the electronic component is at least partially exposed with respect to the encapsulant. Such an exposed main surface of the carrier's component mounting area may allow to efficiently remove heat generated by the at least one electronic component during operation of the package. Since the carrier may be made partially or entirely from a metallic material which may also have a high thermal conductivity, heat removal by an exposed carrier surface may be much more efficient than through material of the encapsulant, having usually a significantly lower thermal conductivity than the carrier. When the carrier is exposed with respect to the encapsulant at one main surface of the package, an exposed electrically conductive surface may be provided which may simplify electrically connecting the package and which may also promote heat dissipation during operation of the package (in particular when the electronic component is a power semiconductor chip).

In an embodiment, the method comprises after said clamping, removing the encapsulation tool pin from the tie bar so that a horizontal surface portion of said tie bar is exposed beyond the encapsulant, and thereafter removing a part of the tie bar which corresponds to the exposed horizontal surface portion and removing an adjacent part of the encapsulant so that a remaining part of the encapsulant vertically covers an entire remaining horizontal surface portion of the tie bar facing the sidewall recess. Hence, the sidewall recess may be formed in a two-stage process. In a first stage, the (preferably tapering) encapsulation tool pin clamps onto the tie bar and is thereafter removed, so that a circumferentially closed blind hole in the encapsulant is obtained having a bottom part defined by tie bar material and having a lateral part defined by encapsulant material. In a second stage, some encapsulant and tie bar material is removed for package singulation in a region including part of said circumferentially closed blind hole so that the latter is converted into the sidewall recess delimited by encapsulant material only.

In an embodiment, the method comprises removing said part of the tie bar and removing said part of the encapsulant by mechanically sawing, in particular by a dicing blade. In particular, the dicing blade may have a breadth which is larger than a diameter (for instance in case of a mold pin with circular end face) and/or a width (for instance in case of a square formed mold pin) of an end face of the encapsulation tool pin contacting the tie bar during said clamping. A general advantageous design rule may be that the mold pin diameter at an end face is smaller than a diameter of a dicing blade or of a dicing street. For example, said breadth is at least 0.45 mm (for instance is 0.5 mm) and/or said diameter and/or said width is not more than 0.35 mm (for instance is 0.3 mm). To put is shortly, the mentioned dimensions are adjusted so that, starting from a circumferentially closed blind hole in the encapsulant with bottom defined by tie bar material is converted, merely by said sawing process, into a sidewall recess delimited exclusively by encapsulant material. To put it shortly, this may be achieved in particular by a sufficiently broad dicing blade.

In an embodiment, the encapsulation tool pin is tapering towards the clamped tie bar. This can be, for example, a conical tapering, a double conical tapering, a tapering with a polygonal cross-section, etc. The tapering shape towards an interior of the encapsulant or towards the tie bar may ensure that after mechanical dicing the bottom of the sidewall recess is vertically spaced from the top side of the tie bar by the encapsulant.

In an embodiment, the encapsulation tool pin has a first tapering section facing away from the clamped tie bar and a connected second tapering section facing the clamped tie bar. Preferably, a first tapering angle of the first tapering section with respect to a central axis of the encapsulation tool pin is smaller than a second tapering angle of the second tapering section with respect to the central axis. This may promote the formation of the sidewall recess with the above-mentioned desired properties.

In an embodiment, the method comprises providing an oblong carrier structure comprising the carrier and at least one additional carrier comprising at least one additional component mounting area from which at least one additional tie bar extends, mounting at least one additional electronic component on the at least one additional component mounting area, encapsulating at least part of the at least one additional electronic component and part of the at least one additional carrier by an oblong encapsulant structure to which also said encapsulant belongs, wherein the at least one additional tie bar is clamped by at least one additional tool pin during at least part of the encapsulating, and separating an obtained structure into individual packages each comprising a respective one of said carriers, a respective one of said electronic components, and a part of said encapsulant structure as a respective encapsulant, so that each of the encapsulants is formed with a respective sidewall having a respective sidewall recess which is partially defined by the respective encapsulation tool pin and which is vertically displaced with respect to a part of the respective tie bar so that the respective encapsulant vertically covers an entire horizontal surface portion of the respective tie bar facing the respective sidewall recess. Thus, multiple packages may be formed in a batch process. Such a batch process may use integral oblong carrier structures having a plurality of carriers connected by tie bars. Moreover, such a batch process may use integral oblong encapsulant structures providing encapsulants for multiple packages. In a singulation process, the oblong carrier structure may be separated into individual carriers and the oblong encapsulant structure may be separated into individual encapsulants, thereby providing a plurality of individual packages.

Still referring to the previously described embodiment, the method may comprise mounting additional electronic components on additional (preferably electrically conductive) carriers (which may be designed as the carrier described above, in particular with one or more tie bars), so that the electronic components and the carriers are arranged in a plurality of rows and columns, encapsulating at least part of the additional carriers and the additional electronic components by additional encapsulant, and sawing vertical sidewalls or side flanks of the encapsulant structure(s) to form separate encapsulants. It may also be possible to provide additional leads or lead sections and to punch leads or lead sections extending beyond the encapsulants. Thus, the manufacturing method may be carried out on leadframe or panel level, i.e. for multiple carriers and for multiple electronic components simultaneously. Such a batch process further reduces the manufacturing effort and allows manufacturing packages on an industrial scale. The carriers and consequently the packages may be arranged in a matrix-like way in rows and columns. Descriptively speaking, sawing may be carried out horizontally, i.e. along the rows, whereas punching may be carried out vertically, i.e. along the columns. In this way, a highly efficient manufacturing process may be obtained.

In particular, the method may comprise forming a plurality of parallel encapsulant structures or bars of material of the encapsulant and the additional encapsulant, wherein each encapsulant structure or bar at least partially encapsulates all carriers and all electronic components of a respective column. According to such a preferred embodiment, encapsulant structures or bars may be formed covering for instance all carriers and electronic components of a column of the matrix-like arrangement of preforms of packages simultaneously. As a result, an arrangement of parallel vertically extending encapsulant bars or structures may be obtained. This may be carried out highly advantageously by molding. In particular, the combination of the formation of vertically extending encapsulant bars with the horizontal extension of the leads or lead sections may be of utmost advantage.

In an embodiment, the method comprises punching lead sections extending beyond the encapsulant and being electrically coupled with the carrier and/or the electronic component. Said punching may lead to a punched surface. In the context of the present application, the term “punched surface” may particularly denote a surface area delimiting the one or more leads and being defined by punching. Punching may denote a forming process that uses a punch press to force a tool, which may be denoted as a punch, through the workpiece to create a hole via shearing. Punching is applicable to a wide variety of materials in sheet form, including sheet metal. Punching is a simple and therefore highly efficient method of defining structures in a patterned sheet material. Correspondingly, a punched surface is a surface defined by punching. A person skilled in the art will understand that a punched surface has dedicated properties which can be easily and unambiguously analysed by a person skilled in the art. At the punched surface delimiting the lead, a corresponding side flank of the encapsulant may be defined by the encapsulation process, in particular by molding. A corresponding encapsulant, such as a mold compound, may comprise a matrix (for instance comprising a resin) with filler particles. At a molded surface corresponding to a punched surface of the leads, the filler particles are coated by matrix material of the in particular mold compound-type encapsulant to form a defined structure with coated pixels on the surface. Moreover, a molded side flank at a punched surface of a corresponding lead may be slanted (for instance with a slanting angle in a range between 6° and 12°, in particular between 8° and 10°) for promoting removal of a corresponding mold body out of a mold tool.

In an embodiment, the method comprises forming another slanted sidewall of the encapsulant by a slanted sidewall of a cavity of an encapsulation tool. Hence, slanted sidewalls may be defined by the geometry of an encapsulation tool which may lead to a molded texture, whereas vertical sidewalls may be defined by mechanically dicing which may result in a sawn texture.

In an embodiment, the method comprises clamping on the tie bar by the encapsulation tool pin during encapsulation so that the component mounting area is pressed onto a counter surface of an encapsulation tool. This may prevent the carrier from tilting during the encapsulation process so that an unintentional flow of encapsulant to the back side of the carrier may be reliably prevented. Hence, undesired phenomena such as mold flash or bleeding may be inhibited.

In an embodiment, a leadframe structure may be used as carrier. In the context of the present application, the term “leadframe” may particularly denote a metal structure comprising an array of initially integrally connected carriers and leads for packages. The electronic components may be attached to the carriers of the leadframe, and then bond wires and/or clips may be provided for attaching pads of the electronic component to leads of the leadframe. Subsequently, the leadframe may be molded in a plastic case or any other encapsulant. Outside and/or inside of the leadframe, corresponding portions of the leadframe may be cut-off, thereby separating the respective leads and/or carriers. A leadframe may be composed of multiple carriers or leadframe structures for electronic components, wherein each carrier may have a component mounting area, at least one tie bar, and one or more leads or lead sections.

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in gallium nitride or silicon carbide technology.

For the encapsulating, a plastic-like material or a ceramic material which may be subsidized by encapsulant additives such as filler particles, additional resins or others may be used.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

A manufacturing architecture for packages involves the formation of common encapsulant structures for a plurality of packages and the subsequent separation by sawing through encapsulant and metallic carrier structures as well as punching through lead structures. A corresponding molding process may be supported with mold pins holding tie bars during molding and includes the above mentioned sawing process as the final singulation.

However, since a cavity is formed by the mold pins over the tie bars, during sawing, burrs from the tie bars may be stuck in these spaces. Thus, due to a conventional pin hole design and due to a mold pin contact with a tie bar during mold clamping, metal debris and/or burrs from tie bar may got stuck inside the package hole during package sawing. This may lead to packages with pronounced burrs which may be beyond an acceptable burr specification.

According to an exemplary embodiment, a package may be provided being encapsulated by an encapsulant, such as a mold compound. The package may have a preferably at least partially electrically conductive carrier having a component mounting area (like a die paddle). One or more electronic components, for instance a semiconductor power chip, may be assembled on the component mounting area. Tie bars may interconnect adjacent carriers of a multi-carrier structure, such as a leadframe for providing mechanical support during a batch manufacturing process. During the manufacturing process, the tie bar may be also used for clamping it down by an encapsulation tool pin against a counter surface of an encapsulation tool. This may avoid unintentional flow of flowable encapsulant material to the bottom of the carrier, thereby preventing mold flash or bleeding of encapsulant material. The temporary presence of the encapsulation tool pin inside the encapsulant may create a hole in the encapsulant having the same shape as the encapsulation tool pin which is removed after encapsulation. By mechanical singulation using for example a mechanical sawing blade, encapsulant material surrounding part of said hole may be removed as tie bar material below will also be removed during singulation. As a result, the pin-shaped hole will be modified into the sidewall recess which may be delimited by encapsulant material only. Consequently, the bottom end of the recess may be located vertically above the tie bar and may be defined by encapsulant material only. Beneficially, the encapsulant may cover the whole upper horizontal surface portion of the tie bar facing the sidewall recess. Advantageously, this configuration may reliably prevent burrs of sawn tie bar material in the recess. The described manufacturing architecture and corresponding package may strongly suppress artefacts like mold flash and/or burrs. The obtained package may be manufactured with excellent reliability and moderate effort.

Thus, an exemplary embodiment may prevent metal debris from depositing into a mold pin hole by processing the latter so that the processed mold pin hole does no longer extend up to the tie bar. This may be achieved by converting the mold pin hole exposing a top side of the die bar into a sidewall recess delimited exclusively by encapsulant material, in particular at a bottom side of the sidewall recess. Such an advantageous configuration may be integrated in particular in encapsulant bar manufacture using a tapered mold pin design. Exemplary embodiments may efficiently suppress copper burr debris inside a package hole. In particular, it may be possible with exemplary embodiments to prevent metal debris from depositing into the hole by using a tapered mold pin and provide a mold layer between the tie bar and the package hole after package sawing, thus preventing the metal debris deposits to the hole. Advantageously, a mold layer may be arranged between tie bar pin and package hole to prevent metal debris deposits to the hole during package sawing. Beneficially, such a manufacturing approach does not involve any change in the solderable footprint.

According to an exemplary embodiments, a method to eliminate deposit of metal debris in a mold pin hole may use a tapered mold pin design. Correspondingly, an exemplary embodiment may provide a mold pin with a taper design, wherein the tip of the mold pin is smaller than the thickness of the saw blade used for package sawing. Advantageously, the tapered mold pin does not completely expose the tie bar, but creates a blind hole, because a layer of epoxy mold compound may be present between pin hole and tie bar. Preferably, the edges of the tie bar may remain covered with epoxy mold compound after package sawing acting as a barrier, thereby eliminating issues with metal burr and/or debris deposition in the pin hole. Advantageously, a slight reduction in the width of the package body by performing singulation of the package at the location of the pins just before chamfer start results in elimination of saw burrs in the pin hole. Thus, exemplary embodiments may resolve a tie bar-caused burr (in particular of copper) or debris trap inside a mold pin package hole.

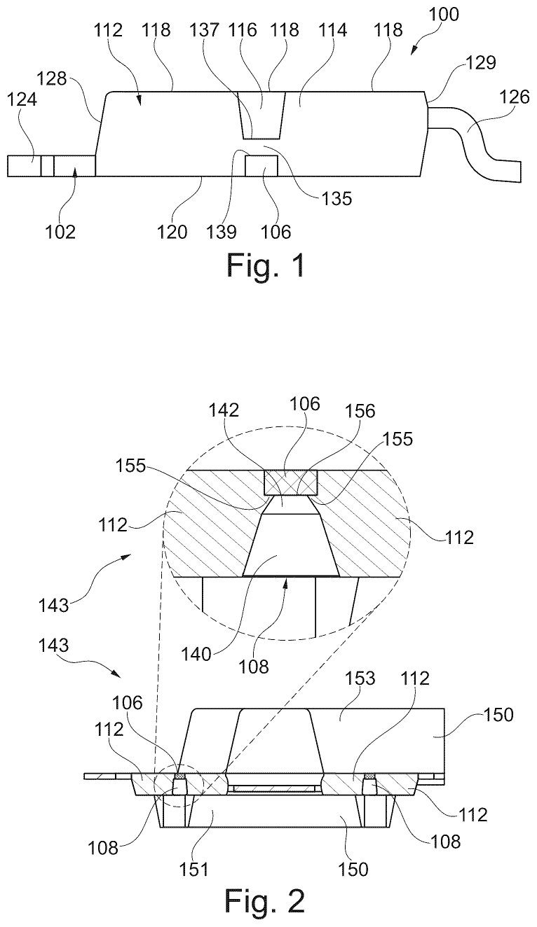

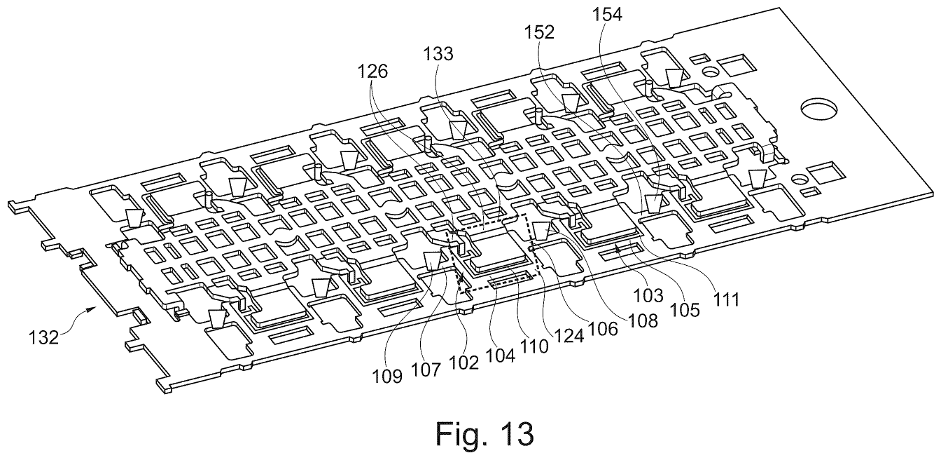

FIG. 1 illustrates a side view of a package 100 according to an exemplary embodiment. Since package 100 of FIG. 1 is already encapsulated by an encapsulant 112 so that the interior of the package 100 is not entirely visible in FIG. 1, reference is made additionally to encircled section 133 in FIG. 13 showing a portion of an interior of package 100 before encapsulation.

The package 100 according to FIG. 1 with an interior configuration as shown in FIG. 13 comprises a carrier 102, which may comprise or consist of a metal such as copper. For instance, said carrier 102 may be embodied as a leadframe structure. Since a major portion of the carrier 102 is encapsulated by an encapsulant 112 (such as a mold compound), said major portion of the carrier 102 is not visible in FIG. 1. The construction of the carrier 102 of the package 100 of FIG. 1 can however be better seen in FIG. 13 showing a preform from which the package 100 of FIG. 1 has been singulated after encapsulation. The carrier 102 comprises a component mounting area 104 which may be embodied as a die pad.

From a lateral side edge of the component mounting area 104, a tie bar 106 extends. For example, the component mounting area 104 and the tie bar 106 may be an integral metallic structure, for instance formed of copper material. The tie bar 106 may be configured for being clamped down by an encapsulation tool pin (see reference sign 108 in FIG. 2) during the process of encapsulation, i.e. during forming the encapsulant 112. This may prevent undesired mold flash or mold bleed at the side of the package 100 at which the component mounting area 104 is exposed beyond the encapsulant 112, which is, although not shown, the bottom side according to FIG. 1. As a consequence and as a fingerprint of this manufacturing process, the encapsulant 112 has a blind hole-type edge recess 116 in a vertical sidewall 114 of the encapsulant 112. Said sidewall recess 116 extends up to only one main surface 118 of two opposing main surfaces 118, 120 of the package 100 or encapsulant 112. The recess 116 is arranged where the encapsulation tool pin 108 had been present during the encapsulation process. Said recess 116 is shaped as a notch extending sidewise and vertically into the encapsulant 112 and is completely delimited by material of the encapsulant 112 without reaching an upper main surface of tie bar 106. In contrast to this, an encapsulant spacer 135 is sandwiched between a bottom wall 137 of recess 116 and a horizontal top surface 139 of tie bar 106. Descriptively speaking, the encapsulant spacer 135 may act as a mold barrier between recess 116 and tie bar 106 for preventing formation of burrs in recess 116. Thus, the recess 116 is fully delimited by the encapsulant 112. However, the tie bar 106 is exposed at vertical sidewall 114, more specifically at a bottom side of vertical sidewall 114 extending up to lower main surface 120 of package 100.

In a way as shown for instance in FIG. 13, an electronic component 110 may be mounted on the component mounting area 104. For instance, the electronic component 110 may be a semiconductor die, such as a power semiconductor die. The electronic component 110 may be assembled on the component mounting area 104 by an electrically conductive connection medium, such as a solder, a sinter material and/or electrically conductive glue. It is also possible that a plurality of electronic components are mounted on the component mounting area 104.

The already mentioned encapsulant 112 may encapsulate the electronic component 110 entirely and the carrier 102 partially. For instance, said encapsulant 112 may be a mold compound. Said encapsulant 112 may encapsulate the electronic component 110 and part of the carrier 102 and may have sidewall 114 with sidewall recess 116 which is vertically displaced with respect to a part of the tie bar 106 by encapsulant spacer 135. The encapsulant 112 vertically covers an entire upper horizontal surface portion of the tie bar 106 facing the sidewall recess 116 above. Consequently, the tie bar 106 is not vertically exposed at the bottom wall 137 of the sidewall recess 116, but is only laterally exposed at said sidewall 114 of the encapsulant 112. Since said sidewall 114 is formed by mechanically dicing using a dicing blade, sidewall 114 is a vertical sidewall with a sawn texture.

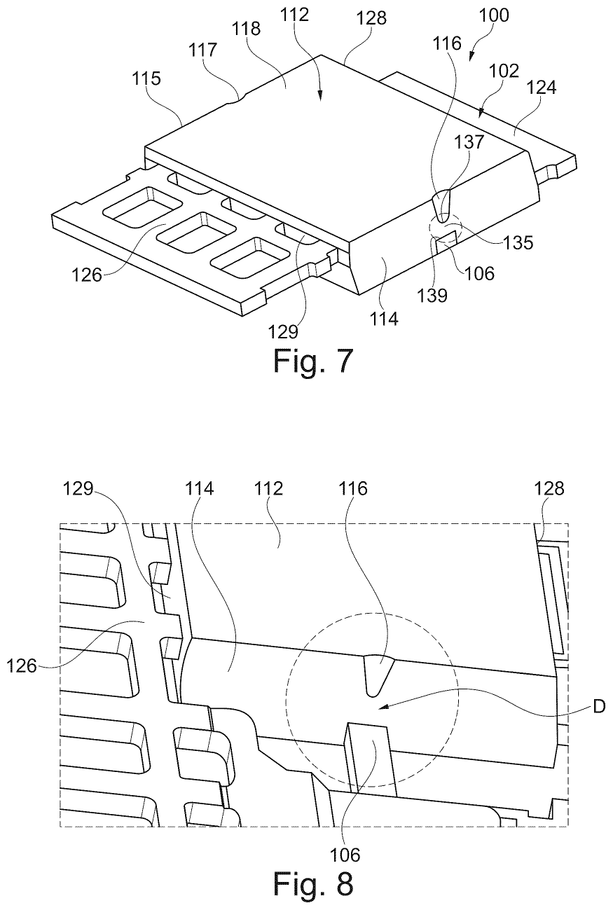

Referring again to FIG. 13, the carrier 102 of FIG. 1 may comprise a further tie bar 107 extending from the component mounting area 104 at an opposing side than the tie bar 106. The further tie bar 107 is configured for being clamped by a further encapsulation tool pin 109, shown as well in FIG. 13, during encapsulation and may then be retracted after curing encapsulant 112 leaving a fully circumferentially closed blind hole behind. Said blind hole may be circumferentially delimited by the encapsulant 112 and may be delimited at a bottom side by the further tie bar 107. Thereafter, some material of encapsulant 112 and of the further tie bar 107 may also be removed during singulation, so that the encapsulant 112 is provided with a vertical further sidewall 115 (which may be shaped corresponding to vertical sidewall 114) with a further sidewall recess 117 (which may be embodied corresponding to sidewall recess 116), see FIG. 7. Again, a bottom wall of further sidewall recess 117 may be vertically displaced with respect to a part of the further tie bar 107, and the encapsulant 112 may again vertically cover an entire horizontal surface portion of the further tie bar 107 facing the further sidewall recess 117. Again referring to FIG. 7, the tie bar 106 and the further tie bar 107 may extend from opposing sides of the component mounting area 104, and the sidewall 114 and the further sidewall 115 may be opposing vertical sidewalls of the encapsulant 112 both having a sawn texture due to the mechanical dicing-type singulation process.

Now referring again to FIG. 1, the sidewall recess 116 is tapering from main surface 118 of the encapsulant 112 and of the package 100 as a whole towards, but not up to the tie bar 106. Thus, the inwardly tapering sidewall recess 116 vertically ends at its bottom wall 137 without reaching horizontal top surface 139 of tie bar 106 and is spaced with respect to the horizontal top surface 139 by the encapsulant spacer 135. Although not shown, also the further sidewall recess 117 is tapering from main surface 118 of the encapsulant 112 and of the package 100 as a whole towards the further tie bar 107. However, the inwardly tapering further sidewall recess 117 vertically ends at a bottom wall thereof without reaching a horizontal top surface of further tie bar 107 and is spaced with respect to said horizontal top surface by a further encapsulant spacer.

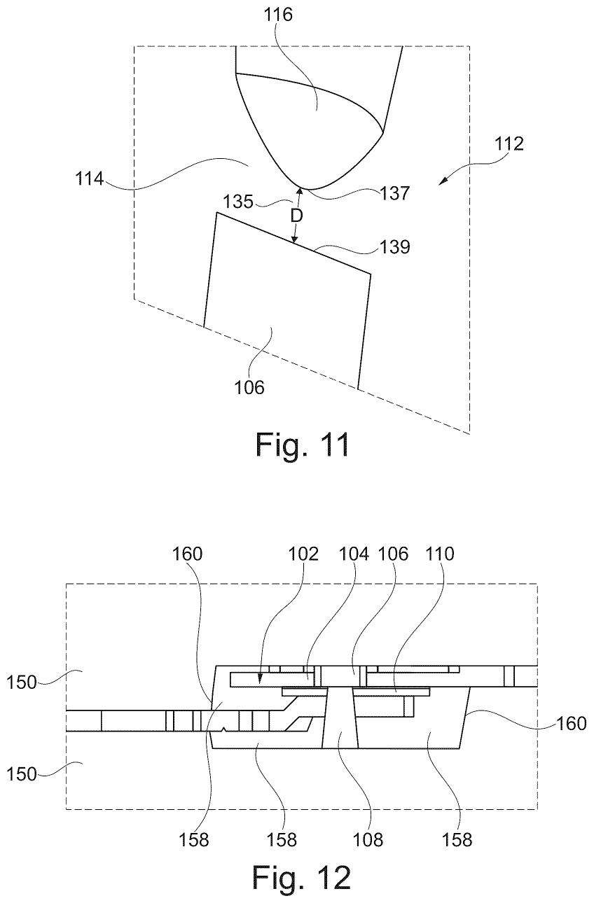

Now briefly referring to FIG. 8, FIG. 10, and FIG. 11, a vertical thickness D of the portion of the encapsulant 112 which vertically covers the horizontal surface portion of the tie bar 106 facing the sidewall recess 116 and constituting the encapsulant spacer 135 may be in a range from 0.1 mm to 0.3 mm, for instance in a range from 0.15 mm to 0.25 mm. The vertical thickness of the portion of the encapsulant 112 which vertically covers the horizontal surface portion of the further tie bar 107 facing the further sidewall recess 117 may be configured correspondingly.

As shown, the sidewall recess 116 is here embodied as a blind hole-notch extending vertically into encapsulant 112 in a blind hole-type fashion while also extending horizontally into sidewall 114. The same is true for the further sidewall recess 117. Advantageously, each of sidewall recesses 116, 117 is exclusively delimited by material of encapsulant 112. This may prevent metallic burrs and debris of sawn tie bars 106, 107 from entering sidewall recesses 116, 117. As a result, package 100 may have high reliability. Furthermore, the sidewall 114 is delimited exclusively by material of the encapsulant 112 and of the tie bar 106. Correspondingly, the further sidewall 115 is delimited exclusively by material of the encapsulant 112 and of the further tie bar 107.

Again referring to FIG. 1 and FIG. 13, the package 100 additionally comprises electrically conductive (preferably metallic, for instance made of copper) lead sections 124, 126 extending partially within and partially outside of the encapsulant 112. Lead section 124 may be integrally formed with the component mounting area 104. Lead section 126 may be a body being separate from the component mounting area 104, but may be electrically coupled with the electronic component 110 and/or with the component mounting area 104 by one or more electrically conductive connection elements (such as clips and/or bond wires). Both lead sections 124, 126 extend out of the encapsulant 112 at two opposing slanted sidewalls 128, 129 of the encapsulant 112. The slanted sidewalls 128, 129 may be defined by a profile of a cavity 158 of an encapsulation tool 150 (see FIG. 12) used for encapsulating package 100, i.e. used for forming encapsulant 112 (preferably by molding). Consequently, the surfaces of the two slanted sidewalls 128, 129 may have a molded texture being the fingerprint of the molding process executed for defining the slanted sidewalls 128, 129.

In contrast to this, the surfaces of the vertical sidewalls 114, 115 are formed by sawing and therefore have a sawn texture. By inspecting the respective texture, a skilled person may distinguish between a sawn texture and a molded texture.

Although not shown in FIG. 1, a main surface of the component mounting area 104 facing away from the encapsulated electronic component 110 and being arranged at a main surface 120 of package 100 is exposed with respect to the encapsulant 112. Thus, heat dissipation from the encapsulated electronic component 110 can occur efficiently via the exposed highly thermally conductive surface of the component mounting area 104. Consequently, main surface 120 of package 100 may be denoted as heat sink side, since a heat sink (not shown) may be optionally attached to the heat dissipating exposed main surface of the component mounting area 104. For instance, such a heat sink may comprise a metallic plate to be attached to the exposed main surface of the component mounting area 104 with a plurality of cooling fins extending from said metallic plate.

The two opposing main surfaces 118, 120 of the package 100 may be parallel to each other. The vertical sidewalls 114, 115 may extend perpendicular to the main surfaces 118, 120. The slanted sidewalls 128, 129 may be slanted with respect to the vertical sidewalls 114, 115 and with respect to the main surfaces 118, 120. For instance, a slanting angle of the slanted sidewalls 128, 129 with respect to the vertical sidewalls 114, 115 may be in a range from 6° to 12°.

With the described package design and corresponding manufacturing process, it may be possible that no saw burrs get stuck in the cavity or recess 116 formed by the mold pin above the tie bar 106. To achieve this, in particular a tapered mold pin design may be advantageous so that, after package sawing, the entire recess 116 will be delimited by material of encapsulant 112 only. In other words, the top side of the tie bar 106 beneath may be completely covered with a mold layer after package sawing. This may lead to a design with, on the top side, unexposed tie bars 106, 107 under a respective package hole in form of recesses 116, 117.

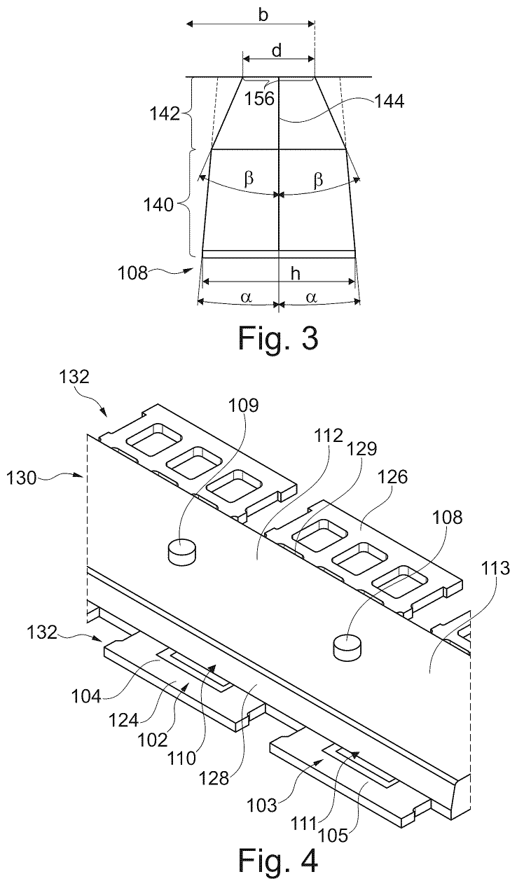

FIG. 2 illustrates an overview (bottom side) and a detail (top side) of an arrangement 143 during manufacture of a package 100 according to an exemplary embodiment. FIG. 3 illustrates an encapsulation tool pin 108 used during manufacture of such a package 100 according to an exemplary embodiment.

More specifically, arrangement 143 comprises an encapsulation tool 150 comprising a first tool 151 and a second tool 153 between which a cavity 158 is formed. In said cavity 158, a carrier 102 with assembled electronic component 110 may be inserted and may be encapsulated for forming encapsulant 112. During said encapsulation process, preferably molding, the tapering encapsulation tool pin 108 shown in FIG. 2 and FIG. 3 may be used. The encapsulation tool pin 108 is here provided with a tapered mold pin design. Such a tapered mold pin will not completely expose a tie bar 106 during encapsulation. In contrast to this, edges 155 of the tie bar 106 are still covered with material of encapsulant 112, such as an epoxy mold compound.

As can be taken from FIG. 2, the encapsulation tool pin 108 is tapering towards the clamped tie bar 106. As best seen in FIG. 3, the double-tapering encapsulation tool pin 108 has a first tapering section 140 facing away from the clamped tie bar 106 and a connected second tapering section 142 facing and contacting the clamped tie bar 106 during use. For instance, first tapering section 140 may be a first frustoconical body being integrally connected with second tapering section 142 which may be a second frustoconical body. A free end of the second tapering section 142 defines an end face 156 pressing against tie bar 106 during encapsulation. In the embodiment of FIG. 2, the mold pin presses onto the tie bar 106 from a bottom side. In another embodiment, the mold pin may also press onto the tie bar 106 from a top side (not shown). As shown, a first tapering angle α of the first tapering section 140 with respect to a central axis 144 of the encapsulation tool pin 108 may be smaller than a second tapering angle β of the second tapering section 142 with respect to the central axis 144. For instance, the first tapering angle α may be a range from 3° to 10° (in particular 5°). For example, the second tapering angle β may be a range from 12° to 40° (in particular 23°). This design may lead to the edges 155 of the tie bar 106 being still covered with material of encapsulant 112, as shown in the detail of FIG. 2.

As already mentioned above, part of the tie bar 106 and part of the encapsulant 112 may be removed during the manufacturing process for creating sidewall recess 116 by mechanically sawing using a dicing blade. Advantageously, said dicing blade may have a breadth b (shown in FIG. 3 for comparison purposes) which is larger than a diameter d of end face 156 of the encapsulation tool pin 108 contacting the tie bar 106 during said clamping. Preferably, said breadth b is at least 0.45 mm (for example 0.5 mm) and said diameter d may be not more than 0.35 mm (for example 0.3 mm). At an opposing end with respect to the end face 156, the encapsulation tool pin 108 may have a diameter h of for instance more than 0.5 mm (for example 0.63 mm). Preferably, sawing by the sawing blade occurs at least over the entire region of the second tapering section 142.

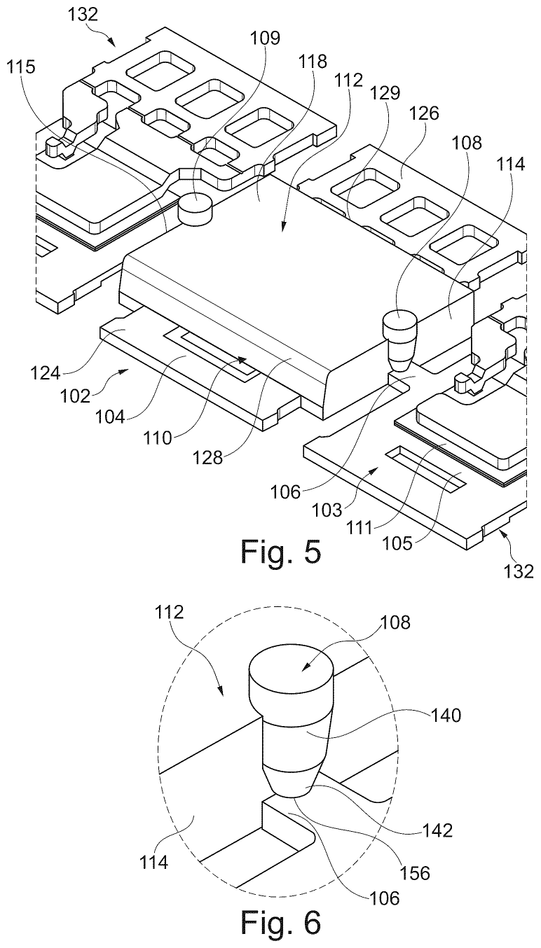

FIG. 4 illustrates a preform of packages 100 during a batch manufacture according to an exemplary embodiment. FIG. 5 illustrates another preform of a package 100 during a batch manufacture according to an exemplary embodiment. FIG. 6 illustrates a detail of FIG. 5. FIG. 7 illustrates a three-dimensional view of a package 100 according to an exemplary embodiment which may be obtained by a manufacturing process according to FIG. 4 to FIG. 6. FIG. 8 illustrates a detail of a preform of the package 100 of FIG. 7.

For manufacturing packages 100, a plurality of carriers 102, 103 may be provided each comprising a component mounting area 104, 105 from which tie bars 106, 107, 152 extend into opposing directions, see FIG. 4, FIG. 5 and additionally FIG. 13. More specifically, it may be possible to provide an oblong carrier structure 132, such as a leadframe, comprising the integrally connected carriers 102, 103.

An electronic component 110, 111 may be mounted or assembled on each of the component mounting areas 104, 105 for example by soldering, sintering or electrically conductive glue (see FIG. 5 and FIG. 13). In FIG. 5, the electronic component 110 is inside the encapsulant 112.

Thereafter, it is possible to encapsulate the electronic components 110, 111 and part of the carriers 102, 103 by a respective encapsulant 112, 113. During this process, the respective tie bar 106, 107, 152 is clamped by an encapsulation tool pin 108, 109, 154 during the encapsulating process. More specifically, it may be possible to clamp on the respective tie bar 106, 107, 152 by the assigned encapsulation tool pin 108, 109, 154 during encapsulation so that the respective component mounting area 104, 105 is pressed onto a counter surface of an encapsulation tool 150 (see FIG. 12). Each encapsulation tool pin 108, 109, 154 may for instance be embodied as chamfered mold pin as described above referring to FIG. 2 and FIG. 3. Beneficially, encapsulating the electronic components 110, 111 and part of the carriers 102, 103 of oblong carrier structure 132 may be accomplished by an oblong encapsulant structure 130 to which said encapsulants 112, 113 belong. Said encapsulation process may be a molding process and said oblong encapsulant structure 130 may be an oblong bar of mold compound.

After said clamping during encapsulating and optionally also during curing encapsulants 112, 113, each encapsulation tool pin 108, 109, 154 is removed from the respective tie bar 106, 107, 152 so that a respective horizontal surface portion of each tie bar 106, 107, 152 is exposed beyond the respective encapsulant 112, 113.

Thereafter, a part of each tie bar 106, 107, 152 which corresponds to the respective exposed horizontal surface portion and an adjacent part of the respective encapsulant 112, 113 are removed so that a remaining part of the respective encapsulant 112, 113 vertically covers an entire remaining horizontal surface portion of the respective tie bar 106, 107, 152 facing the respective sidewall recess 116, 117. This removal process may be accomplished by mechanically sawing using a sawing blade (not shown) during a singulation process by which a plurality of individual packages 100 are created.

As a result and now referring to FIG. 5 to FIG. 7, each individual encapsulant 112, 113 of each individual package 100 is formed with a vertical sidewall 114, 115 having a sidewall recess 116, 117 which is partially defined by the respective encapsulation tool pin 108, 109, 154 and which is vertically displaced with respect to a part of the assigned tie bar 106, 107, 152. This may be accomplished in such a way that the respective encapsulant 112, 113 vertically covers an entire upper horizontal surface portion of the respective tie bar 106, 107, 152 facing the bottom of the sidewall recess 116, 117.

During the described singulation process, a structure obtained after encapsulation and removal of the encapsulation tool pins 108, 109, 154 may be separated into individual packages 100. Each package 100 may then comprise a respective one of said carriers 102, 103, a respective one of said electronic components 110, 111, and a part of said encapsulant structure 130 in form of a respective encapsulant 112, 113. Advantageously, each of the obtained encapsulants 112, 113 is formed with respective sidewalls 114, 115 having respective sidewall recesses 116, 117 being partially defined by the respective encapsulation tool pins 108, 109, 154. Each sidewall recess 116, 117 is vertically displaced with respect to a part of the respective tie bar 106, 107, 152 so that the respective encapsulant 112, 113 vertically covers an entire horizontal surface portion of the respective tie bar 106, 107, 152 facing the respective sidewall recess 116, 117.

During the described manufacturing method, two further slanted sidewalls 128, 129 of each encapsulant 112, 113 may be formed and defined by a slanted sidewall 160 of a cavity 158 of an encapsulation tool 150, see FIG. 12. During the manufacturing method, it may be further possible to punch lead sections 124, 126 extending beyond each encapsulant 112, 113 and being electrically coupled with the respective carrier 102, 103 and the respective electronic component 110, 111.

FIG. 7 shows a package 100 with a final mold body after saw singulation. FIG. 7 also shows that, thanks to the chamfered pin and a corresponding design of the final mold body it may be possible to reduce or even eliminate sawing burrs. Package sawing may remove a tapered pin region by using a package saw blade with sufficient breadth or thickness, for example at least 0.5 mm. A layer of epoxy mold compound or another encapsulant 112 may be formed between the pin holes to the tie bar 106, 107 thereby acting as barrier for metal burr deposition to the pin hole.

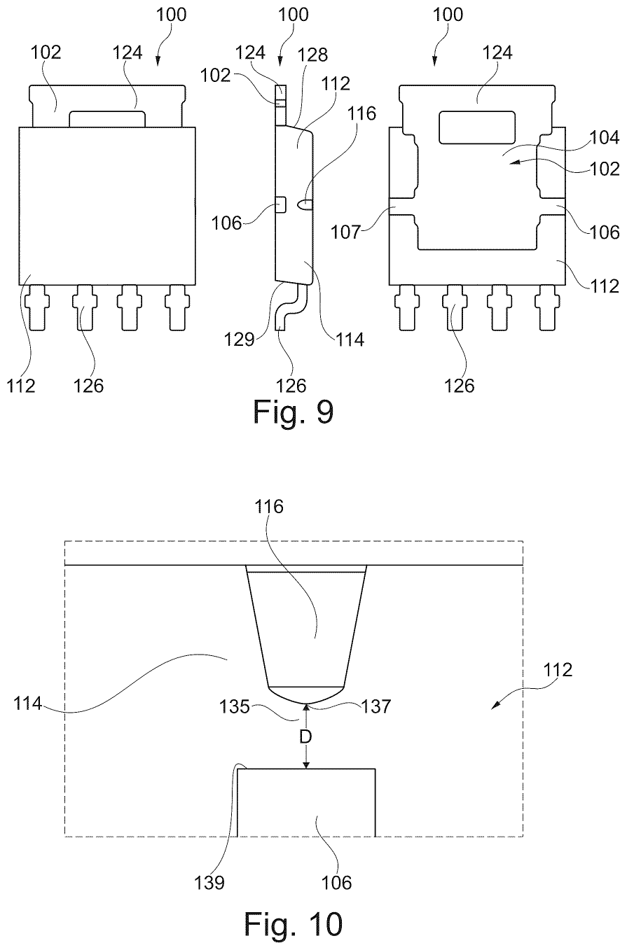

FIG. 9 illustrates different views of a package 100 according to an exemplary embodiment. More specifically, FIG. 9 shows a plan view (left-hand side), a side view (central image) and a bottom view (right-hand side) of package 100.

FIG. 10 illustrates a detail of a package 100 according to an exemplary embodiment. FIG. 11 illustrates another detail of package 100 according to another exemplary embodiment. FIG. 10 and FIG. 11 show a simulation assuming a blade having a breadth b of 0.5 mm. The impact to the mold gap from tie bar to hole is analyzed. In FIG. 10, distance D is 0.235 mm, whereas distance D is 0.118 mm in FIG. 11. FIG. 10 relates to a normal blade having a breadth b of 0.5 mm without deviation. FIG. 11 relates to a blade having a breadth b of 0.5 mm with deviation of ±0.05 mm.

FIG. 12 illustrates an encapsulation tool 150 used for manufacturing a package 100 according to an exemplary embodiment. FIG. 12 shows an orientation of constituents of a package 100 during manufacture. Said constituents, as described above, are arranged in a cavity 158 of encapsulation tool 150 having a bottom-sided tool part and a top-sided tool part. FIG. 12 illustrates package orientation of fixed tie bar pin during molding.

FIG. 13 illustrates a preform of packages 100 during a batch manufacture according to an exemplary embodiment. Reference has already been made to FIG. 13 in the above description. FIG. 13 illustrates the function of mold pins pressing on the package tie bars during encapsulation. The mold pins add support and stability during mold clamping. This may prevent mold flashes for lead height deviations.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier comprising a component mounting area from which a tie bar extends, the tie bar being configured for being clamped by an encapsulation tool pin during encapsulation;
an electronic component mounted on the component mounting area; and
an encapsulant encapsulating at least part of the electronic component and part of the carrier and having a sidewall with a sidewall recess which is vertically displaced with respect to a part of the tie bar;
wherein the encapsulant vertically covers an entire horizontal surface portion of the tie bar facing the sidewall recess.

2. The package according to claim 1, wherein the tie bar is laterally exposed at said sidewall of the encapsulant.

3. The package according to claim 1, wherein said sidewall is a vertical sidewall.

4. The package according to claim 1, wherein the carrier comprises a further tie bar extending from the component mounting area and configured for being clamped by a further encapsulation tool pin during encapsulation, wherein the encapsulant has a further sidewall with a further sidewall recess which is vertically displaced with respect to a part of the further tie bar, and wherein the encapsulant vertically covers an entire horizontal surface portion of the further tie bar facing the further sidewall recess.

5. The package according to claim 4, wherein the tie bar and the further tie bar extend from opposing sides of the component mounting area, and wherein the sidewall and the further sidewall are opposing sidewalls of the encapsulant.

6. The package according to claim 1, wherein the sidewall recess is tapering from a main surface of the encapsulant towards the tie bar.

7. The package according to claim 1, wherein a vertical thickness of a portion of the encapsulant which vertically covers the entire horizontal surface portion of the tie bar facing the sidewall recess is in a range from 0.1 mm to 0.3 mm.

8. The package according to claim 1, wherein the sidewall recess is a blind hole-notch.

9. The package according to claim 1, wherein the sidewall is delimited exclusively by material of the encapsulant and of the tie bar.

10. The package according to claim 1, comprising at least one of the following features:
comprising one or more electrically conductive lead sections, in particular at least one of which being integrally formed with the component mounting area and/or at least one of which being formed separately from the component mounting area, extending out of the encapsulant at one or two slanted sidewalls of the encapsulant, said one or two slanted sidewalls in particular having a molded texture;
wherein a main surface of the component mounting area facing away from the electronic component is at least partially exposed with respect to the encapsulant;
wherein the sidewall has a sawn texture.

11. A method of manufacturing a package, the method comprising:
providing a carrier comprising a component mounting area from which a tie bar extends;
mounting an electronic component on the component mounting area;
encapsulating at least part of the electronic component and part of the carrier by an encapsulant, wherein the tie bar is clamped by an encapsulation tool pin during at least part of the encapsulating; and
forming the encapsulant with a sidewall having a sidewall recess which is partially defined by the encapsulation tool pin and which is vertically displaced with respect to a part of the tie bar so that the encapsulant vertically covers an entire horizontal surface portion of the tie bar facing the sidewall recess.

12. The method according to claim 11, wherein the method comprises
after said clamping, removing the encapsulation tool pin from the tie bar so that a horizontal surface portion of said tie bar is exposed beyond the encapsulant; and
thereafter removing a part of the tie bar which corresponds to the exposed horizontal surface portion and removing an adjacent part of the encapsulant so that a remaining part of the encapsulant vertically covers an entire remaining horizontal surface portion of the tie bar facing the sidewall recess.

13. The method according to claim 12, wherein the method comprises removing said part of the tie bar and removing said part of the encapsulant by mechanically sawing, in particular by a dicing blade, wherein in particular the dicing blade has a breadth which is larger than a diameter and/or a width of an end face of the encapsulation tool pin contacting the tie bar during said clamping, wherein more particularly said breadth is at least 0.45 mm and/or said diameter and/or a width is not more than 0.35 mm.

14. The method according to claim 11, wherein the encapsulation tool pin is tapering towards the clamped tie bar.

15. The method according to claim 11, wherein the encapsulation tool pin has a first tapering section facing away from the clamped tie bar and a connected second tapering section facing the clamped tie bar.

16. The method according to claim 15, wherein a first tapering angle of the first tapering section with respect to a central axis of the encapsulation tool pin is smaller than a second tapering angle of the second tapering section with respect to the central axis.

17. The method according to claim 11, wherein the method comprises:
providing an oblong carrier structure comprising the carrier and at least one additional carrier comprising at least one additional component mounting area from which at least one additional tie bar extends;
mounting at least one additional electronic component on the at least one additional component mounting area;
encapsulating at least part of the at least one additional electronic component and part of the at least one additional carrier by an oblong encapsulant structure to which also said encapsulant belongs, wherein the at least one additional tie bar is clamped by at least one additional tool pin during at least part of the encapsulating; and
separating an obtained structure into individual packages each comprising a respective one of said carriers, a respective one of said electronic components, and a part of said encapsulant structure as a respective encapsulant, so that each of the encapsulants is formed with a respective sidewall having a respective sidewall recess which is partially defined by the respective encapsulation tool pin and which is vertically displaced with respect to a part of the respective tie bar so that the respective encapsulant vertically covers an entire horizontal surface portion of the respective tie bar facing the respective sidewall recess.

18. The method according to claim 11, wherein the method comprises forming another slanted sidewall of the encapsulant by a slanted sidewall of a cavity of an encapsulation tool.

19. The method according to claim 11, wherein the method comprises punching lead sections extending beyond the encapsulant and being electrically coupled with the carrier and/or the electronic component.

20. The method according to claim 11, wherein the method comprises clamping on the tie bar by the encapsulation tool pin during encapsulation so that the component mounting area is pressed onto a counter surface of an encapsulation tool.
